(19) United States
(12) Patent Application Publication
(10) Pub. No.: US 2024/0072101 A1
(43) Pub. Date: Feb. 29, 2024

(54) LED ARRAY

(71) Applicants: SHARP KABUSHIKI KAISHA, Sakai City (JP); Meijo University, Nagoya (JP)

(72) Inventors: YOSHIHIRO UETA, Sakai City, Osaka (JP); Motoaki IWAYA, Nagoya (JP); Yoshinobu SUEHIRO, Nagoya (JP); Yuta IMAIZUMI, Nagoya (JP); Tatsunari SAITO, Nagoya (JP)

(73) Assignees: SHARP KABUSHIKI KAISHA, Sakai City, Osaka (JP); Meijo University, Nagoya (JP)

(21) Appl. No.: 18/230,626

(22) Filed: Aug. 5, 2023

(30) Foreign Application Priority Data
Aug. 25, 2022 (JP) 2022-134362

(51) Int. Cl. H01L 27/15

(52) U.S. Cl. CPC H01L 27/156

(57) ABSTRACT

An LED array includes: a substrate having a depressing-projecting structure formed on a surface of the substrate; a planarization layer formed on the depressing-projecting structure; a plurality of micro LED elements each of which is formed on the planarization layer; and a stray light attenuating groove formed between a pair of adjacent micro LED elements among the plurality of micro LED elements, and extending from toward the pair of micro LED elements to toward the depressing-projecting structure at least part way of the planarization layer.

### CROSS-REFERENCE TO RELATED APPLICATION

The present application claims priority from Japanese Application JP2022-134362, the content of which is hereby incorporated by reference into this application.

### BACKGROUND OF THE INVENTION

### 1. Field of the Invention

The present disclosure relates to an LED array including a plurality of micro LED elements.

### 2. Description of the Related Art

A conventional light-emitting element known in the art includes: a substrate whose surface has a depressing-projecting structure; a planarization layer formed on the depressing-projecting structure; and a light-emitting layer formed on the planarization layer and emitting light in an ultraviolet region, wherein the depressing-projecting structure has a projecting portion above which a cavity is provided (International Publication No. WO 2015/025631).

However, the LED array including a plurality of micro LED elements has a problem: If just one of the plurality of micro LED elements emits light, stray light propagates to non-light-emitting micro LED elements around the one light-emitting micro LED element. The light reflected on side walls of the non-light-emitting micro LED elements is released to the front, and, inevitably, the non-light-emitting micro LED elements appear to falsely glow. The false glow of a display panel including an LED array poses an obstacle to accurate presentation of an image, thereby causing a significant technical problem.

An aspect of the present disclosure is intended to implement an LED array capable of attenuating stray light caused by light emitted from a micro LED element.

In order to solve the above problem, an LED array according to an aspect of the present disclosure includes: a substrate having a depressing-projecting structure formed on a surface of the substrate; a planarization layer formed on the depressing-projecting structure; a plurality of micro LED elements each of which is formed on the planarization layer; and a stray light attenuating groove formed between a pair of adjacent micro LED elements among the plurality of micro LED elements, and extending from toward the pair of micro LED elements to toward the depressing-projecting structure at least part way of the planarization layer.

The aspect of the present disclosure can implement an LED array capable of attenuating stray light caused by light emitted from a micro LED element.

### BRIEF DESCRIPTION OF THE DRAWINGS

FIG. 1 is a plan view of an LED array according to an embodiment;

FIG. 2 is a cross-sectional view taken along plane AA illustrated in FIG. 1;

FIG. 3 is a cross-sectional view of an LED array according to a comparative example;

FIG. 4 is a plan view showing dimensions of micro LED elements as a condition for optical simulations of the LED array.

FIG. 5 is a cross-sectional view showing a condition for the optical simulations of the LED array.

FIG. 6 is a graph showing a simulation result of stray light generated when a depressing-projecting structure is not formed on a substrate;

FIG. 7 is a graph showing stray light generated when the depressing-projecting structure is formed on the substrate;

FIG. 8 is a graph showing stray light generated when dimensions of the depressing-projecting structure are reduced;

FIG. 9 is an image showing a simulation result of stray light observed when no stray light attenuating groove is provided;

FIG. 10 is an image showing a simulation result of stray light observed when a stray light attenuating groove having a depth of 3 μm is provided;

FIG. 11 is an image showing a simulation result of stray light observed when a stray light attenuating groove having a depth of 4 μm is provided;

FIG. 12 is an image showing a simulation result of stray light observed when a stray light attenuating groove having a depth of 5 μm is provided;

FIG. 13 is an image showing a simulation result of stray light observed when FIG. 9 is overlapped with shapes of pixels;

FIG. 14 is an image showing a simulation result of stray light observed when FIG. 10 is overlapped with shapes of pixels;

FIG. 15 is an image showing a simulation result of stray light observed when FIG. 11 is overlapped with shapes of pixels;

FIG. 16 is an image showing a simulation result of stray light observed when FIG. 12 is overlapped with shapes of pixels;

FIG. 17 is an image showing an experimental result of stray light observed when no stray light attenuating groove is formed;

FIG. 18 is an image showing an experimental result of stray light observed when a stray light attenuating groove having a depth of 3 μm is formed;

FIG. 19 is an image showing an experimental result of stray light observed when a stray light attenuating groove having a depth of 4 μm is formed;

FIG. 20 is an image showing an experimental result of stray light observed when a stray light attenuating groove having a depth of 5 μm is formed; and

FIG. 21 is an image showing a result of tracking light rays around the depressing-projecting structure.

### DETAILED DESCRIPTION OF THE INVENTION

### First Embodiment

An embodiment of the present disclosure will be described below in detail.

Configuration of LED Array 1

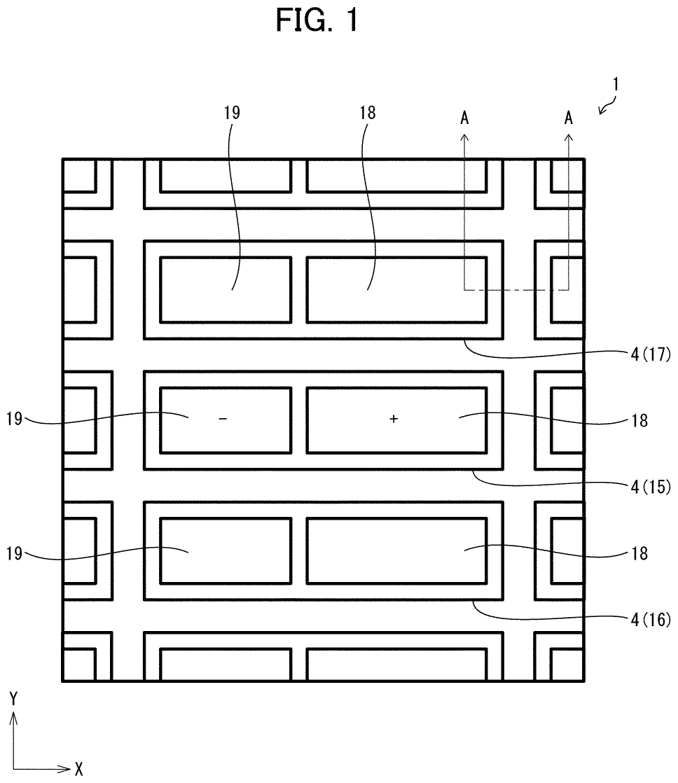

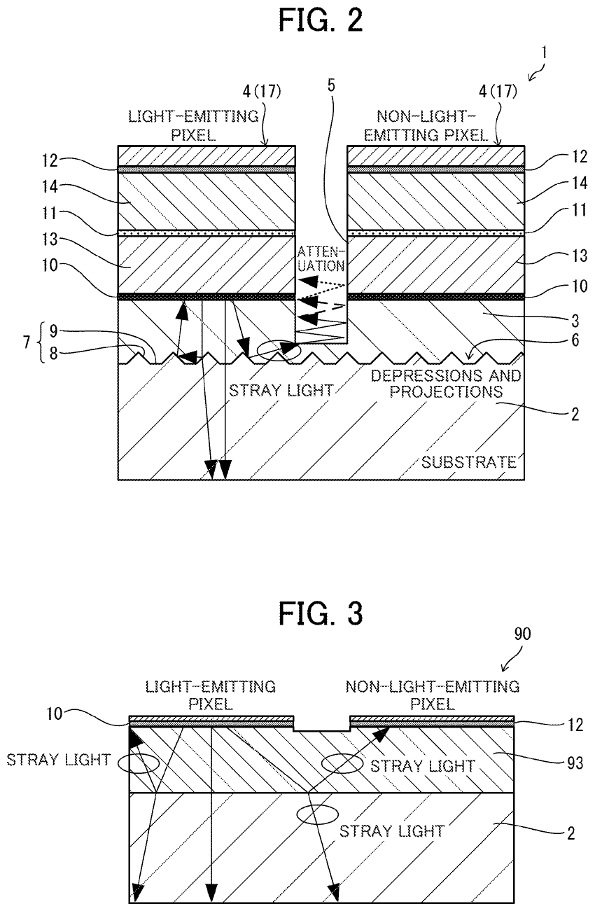

FIG. 1 is a plan view of an LED array 1 according to an embodiment. FIG. 2 is a cross-sectional view taken along plane AA illustrated in FIG. 1.

As illustrated in FIG. 1, the LED array 1 includes a plurality of micro LED elements 4 formed in an array in an X-direction and a Y-direction.

As illustrated in FIG. 2, the LED array 1 includes: a substrate 2 having a depressing-projecting structure 6 periodically formed on a surface of the substrate 2; a planarization layer 3 formed on the depressing-projecting structure 6; the plurality of micro LED elements 4 each of which is formed on the planarization layer 3 in an array in the X-direction and the Y-direction; and a stray light attenuating groove 5 formed between a pair of adjacent micro LED elements 4 among the plurality of micro LED elements 4, and extending from toward the micro LED elements 4 to toward the depressing-projecting structure 6 at least part way of the planarization layer 3. The stray light attenuating groove 5 has a depth preferably exceeding 4 μm. The planarization layer 3 is formed of a semiconductor layer.

The substrate 2 can be formed of a typical c-plane sapphire substrate.

The planarization layer 3 is a layer having a function of planarizing depressions and projections of the depressing-projecting structure 6 formed on the substrate 2. The planarization layer 3 is made of a semiconductor material.

Specifically, the stray light attenuating groove 5 separates the plurality of micro LED elements 4 from one another, and reaches at least part way of the planarization layer 3.

The depressing-projecting structure 6 includes a plurality of depressing-projecting units 7 formed on the surface of the substrate 2. In the example illustrated in FIG. 2, the surface of the substrate 2 is provided with projecting portions to form the depressing-projecting units 7. The surface of the substrate 2 may be provided with depressing portions to form the depressing-projecting units 7.

Each of the depressing-projecting units 7 includes: an inclined surface 8; and a bottom surface 9 connected to the inclined surface 8. The bottom surface 9 may have a shape of a circle, an ellipse, or a polygon in planar view, and the shape of the bottom surface 9 is not limited to a particular shape.

A dimension of the inclined surface 8 (hereinafter referred to as a first dimension) in a direction in parallel with a surface of the substrate 2 is preferably ½ or more of a wavelength of the light emitted from a micro LED element 4, and 2 μm or less. The first dimension means a width of the inclined surface 8 observed when the projecting portion or the depressing portion is observed in planar view from a direction perpendicular to the surface of the substrate 2. If the surface of the substrate 2 is provided with a projecting portion, the width of the inclined surface 8 means the shortest distance between a ridge line defined by a tip portion of the projecting portion and an outer edge of the bottom surface 9 when the substrate 2 is viewed in planar view. Furthermore, if the surface of the substrate 2 is provided with a depressing portion, the width of the inclined surface 8 means the shortest distance between a notch groove serving as the depressing portion and an outer edge of a projecting portion corresponding to the bottom surface 9 in FIG. 2 when the substrate 2 is viewed in planar view.

A dimension of the inclined surface 8 in a direction perpendicular to the substrate 2; that is, a height of the projecting portion or a depth of the depressing portion is ½ or more of a wavelength of the light emitted from a micro LED element 4, and 2 μm or less. This inclined surface 8 is inclined at an inclination angle at which the light emitted from the micro LED element 4 is reflected and guided to the stray light attenuating groove 5.

As described above, the depressing-projecting structure 6 may include projecting portions formed on the surface of the substrate 2. On each of the projecting portions, the inclined surface 8 may be formed. The depressing-projecting structure 6 may further include the bottom surface 9 connected to the inclined surface 8. Furthermore, the depressing-projecting structure 6 may include depressing portions formed on the surface of the substrate 2. On each of the depressing portions, the inclined surface 8 may be formed. The depressing-projecting structure 6 may further include the bottom surface 9 connected to the inclined surface 8. The bottom surface 9 may have a shape of a circle, an ellipse, or a polygon.

Preferably, one or more of the depressing-projecting units 7 are provided per a region (that is, an area included in the surface of the substrate 2 and occupied by one micro LED element 4), on the substrate 2, corresponding to each micro LED element 4.

As illustrated in FIG. 1, each of the plurality of micro LED elements 4 may be any of a first light-emitting element 15, a second light-emitting element 16, or a third light-emitting element 17. The first light-emitting element 15 is a light-emitting element including a first light-emitting layer 10 that emits a blue light (light in a first color). The second light-emitting element 16 is a light-emitting element including: the first light-emitting layer 10; and a second light-emitting layer 11 stacked above the first light-emitting layer 10 and emitting a green light (light in a second color). The third light-emitting element 17 is a light-emitting element including: the first light-emitting layer 10; the second light-emitting layer 11; and a third light-emitting layer 12 stacked above the second light-emitting layer 11 and emitting a red light (light in a third color). Each of the first light-emitting element 15, the second light-emitting element 16, and the third light-emitting element 17 includes an anode 18 and a cathode 19.

The second light-emitting element 16 is formed of the third light-emitting element 17 while the third light-emitting layer 12 is removed. The first light-emitting element 15 is formed of the third light-emitting element 17 while the third light-emitting layer 12 and the second light-emitting layer 11 are removed.

For the sake of simplicity, FIG. 2 illustrates the third light-emitting element 17 having a multilayer stacking structure including all of the third light-emitting layer 12, the second light-emitting layer 11, and the first light-emitting layer 10. In the third light-emitting element 17, the third light-emitting layer 12 emits light. The second light-emitting layer 11 and the first light-emitting layer 10 are merely stacked and do not emit light. In the second light-emitting element 16, the second light-emitting layer 11 and the first light-emitting layer 10 are stacked. The second light-emitting layer 11 emits light, and the first light-emitting layer 10 is merely stacked and does not emit light. In the first light-emitting element 15, only the first light-emitting layer 10 is stacked and emits light. FIG. 2 illustrates a multilayer structure of the third light-emitting element 17 in which the third light-emitting layer 12 emits light. For the sake of illustration, FIG. 2 shows a course of the light emitted from the first light-emitting layer 10 of the first light-emitting element 15.

As can be seen, the micro LED element 4 has the multilayer stacking structure including: the first light-emitting layer 10 that emits a blue light (light in the first color); the second light-emitting layer 11 that emits a green light (light in the second color); and the third light-emitting layer 12 that emits a red light (light the third color). The first light-emitting layer 10, the second light-emitting layer 11, and the third light-emitting layer 12 are stacked on top of another.

In the micro LED element 4, the third light-emitting element 17 includes: a first semiconductor layer 13 provided between the first light-emitting layer 10 and the second light-emitting layer 11; and a second semiconductor layer 14 provided between the second light-emitting layer 11 and the third light-emitting layer 12. A clearance between the first light-emitting layer 10 and the second light-emitting layer 11, and a clearance between the second light-emitting layer 11 and the third light-emitting layer 12, have a thickness of preferably 1 μm or more.

As described above, each micro LED element 4 preferably has a monolithic structure including the third light-emitting layer 12, the second light-emitting layer 11, and the first light-emitting layer 10, which respectively emit a red light, a green light, and a blue light, are stacked on top of another in a direction crossing the substrate 2. The first light-emitting element 15, the second light-emitting element 16, and the third light-emitting element 17 constitute one pixel of the LED array 1. The one pixel includes the first light-emitting element 15, the second light-emitting element 16, and the third light-emitting element 17 each of which serves as a subpixel. The subpixel has a height greater than, or equal to, a wavelength of emitted light. Between the subpixels, and between the pixels, the stray light attenuating groove 5 is provided so that the subpixels, and the pixels, are arranged with intervals of 1 μm or more. Between the subpixels, and between the pixels, the stray light attenuating groove 5 may be formed in the planarization layer 3 etched and removed to the surface of the substrate 2.

The stray light attenuating groove 5 extends preferably to a position in which the planarization layer 3 is left to have a thickness of 3 μm or less from the surface of the substrate 2. In other words, the planarization layer 3 is preferably etched to have a thickness of 3 μm or less.

At this time, a side wall of the stray light attenuating groove 5 may be covered with a dielectric film so that the dielectric film protects the element structure and ensures insulation between adjacent elements. The dielectric film can be made of: inorganic compounds such as SiO₂ and SiN typically used in semiconductor processes; or organic substances such as various kinds of acrylic-based, epoxy-based, and silicone-based insulating resins, and polyimide.

Operation of LED Array 1

As to the LED array 1 in the above configuration, the red light emitted from the third light-emitting layer 12 of the third light-emitting element 17 passes through the second light-emitting layer 11 and the first light-emitting layer 10, which are turned OFF, and travels toward the depressing-projecting structure 6 of the substrate 2. Then, the green light emitted from the second light-emitting layer 11 of the second light-emitting element 16 passes through the first light-emitting layer 10, which is turned OFF, and travels toward the depressing-projecting structure 6 of the substrate 2. Furthermore, the blue light emitted from the first light-emitting layer 10 of the first light-emitting element 15 directly travels toward the depressing-projecting structure 6 of the substrate 2.

As will be described below with reference to the blue light emitted from the first light-emitting layer 10, first, the blue light incident on the inclined surface 8 of the depressing-projecting unit 7 is reflected as stray light toward the stray light attenuating groove 5. Then, the stray light reflected toward the stray light attenuating groove 5 is incident on the stray light attenuating groove 5, and reflected on one of the side walls of the stray light attenuating groove 5. Next, the stray light reflected on the one side wall of the stray light attenuating groove 5 is reflected on another side wall. In this way, the stray light is multiply reflected on one side wall and the other side wall of the stray light attenuating groove 5, and is scattered and attenuated. As a result, the stray light propagating from the light-emitting pixel to the non-light-emitting pixel is reduced.

Another portion of the blue light incident on the inclined surface 8 is reflected on another part of the inclined surface 8 in a direction back to the first light-emitting layer 10. The blue light entered from the first light-emitting layer 10 and incident on the bottom surface 9 of the depres sing-projecting unit 7 passes through the bottom surface 9 and propagates inside the substrate 2.

As to the green light emitted from the second light-emitting layer 11 of the second light-emitting element 16 and the red light emitted from the third light-emitting layer 12 of the third light-emitting element 17, the stray light propagating from a light-emitting pixel to a non-light-emitting pixel is reduced in the same manner as the blue light emitted from the first light-emitting layer 10 of the first light-emitting element 15.

### Comparative Example

FIG. 3 is a cross-sectional view of an LED array 90 according to a comparative example. Constituent features similar to those previously described are designated with similar reference signs, and the detailed description of such constituent features will not be elaborated upon repeatedly.

The blue light emitted from the first light-emitting layer 10 has intensity distributed in a stacking direction of the semiconductor multilayer structure. A difference in refractive index at an interface between a semiconductor layer 93 and the substrate 2 is smaller than a difference in refractive index at an interface between the semiconductor layer 93 and the atmosphere. Hence, some of the light distributed in the stacking direction spreads in an in-plane direction of the substrate 2, and becomes stray light. While propagating in the in-plane direction of the substrate 2, this stray light is reflected on a side wall of each pixel in the front direction of the panel. The stray light falsely makes non-light-emitting pixels, and the surroundings of the non-light-emitting pixels, look glowing even though the non-light-emitting pixels are supposed to be turned OFF. If a non-light-emitting pixel falsely glows, the non-light-emitting pixel, which is supposed to be turned OFF, acts as if it were emitting light. That is why an image cannot be accurately presented.

Optical simulations and experiments have found that there are multiple factors and optical paths to cause the false glow, and a countermeasure has to be devised for each of the factors and the optical paths. The present disclosure provides a structure that reduces stray light, among the multiple factors, that strongly appears around a non-light-emitting pixel adjacent to a light-emitting pixel.

The light reaching the substrate 2 is refracted at the interface between the semiconductor layer 93 and the substrate 2, enters the substrate 2, and dispersedly exits from a back surface of the substrate 2. At this time, the light has a component spreading in the in-plane direction of the substrate 2 near the interface between the semiconductor layer 93 and the substrate 2. The light component has a relatively strong intensity, thereby creating strong stray light around the light-emitting pixel. This stray light is generated of a component: propagating through the interface between the semiconductor layer 93 and the substrate 2; and multiply reflected between the side walls of the adjacent pixels. A possible countermeasure to the stray light is to either: reduce the propagation of the stray light, found at the interface between the semiconductor layer 93 and the substrate 2, into the substrate face; or reduce the multiple reflection between the adjacent pixels. More essentially, the present disclosure relates to a structure that reduces propagation of stray light, found at the interface between the semiconductor layer 93 and the substrate 2, into the substrate face.

In this embodiment, the surface of the substrate 2 is provided with the depressing-projecting structure 6 including the inclined surface 8 and flatly embedded into a semiconductor layer serving as the planarization layer 3. On the substrate 2 planarized in such a manner, the plurality of micro LED elements 4 are prepared as a pixel structure.

Because of a difference in refractive index between the depressing-projecting structure 6 and the semiconductor layer serving as the planarization layer 3, the light from the micro LED element 4 is reflected. However, the inclined surface 8 of the depressing-projecting structure 6 has an angle not perpendicular to the surface of the substrate 2. Hence, the light incident on the inclined surface 8 is reflected at a narrow angle (a small angle) with respect to the surface of the substrate 2. At this time, for sufficient reflection on the depressing-projecting structure 6, a size of the depressions and the projections; that is, for example, a size of the bottom surface 9 of the depressing-projecting unit 7, is larger than, or equal to, a wavelength of light emitted from a micro LED element 4. The height or the depth of the depressions and the projections is desirably greater than, or equal to, the wavelength of the light. However, the depressions and the projections have to be embedded flat by semiconductor crystal growth, such that the height or the depth of the depressions and projections is desirably 2 μm or less.

Removing Semiconductor Layer between Pixels, and Monolithic Structure The reflection on the depressing-projecting structure 6 is made at a narrow angle with respect to the surface of the substrate 2. Hence, when the planarization layer 3 serving as the semiconductor layer between the pixels is present, if any, there exists light propagating through the semiconductor layer over the entire surface of the substrate, thereby generating stray light in a wide range. This mechanism is the same as that for improving the light releasing effect described in, for example, Patent Document 1. On the other hand, the LED array 1 is characterized by the monolithic structure of the micro LED element 4, and the structure in which the semiconductor layer serving as the planarization layer 3 between the pixels is removed while a thickness of at least 3 μm is left from an outermost surface of the depressions and the projections on the surface of the substrate 2. Such structures reduce the stray light propagating in a wide area.

Because of the depressing-projecting structure 6 on the surface of the substrate 2, the light reflected at a narrow angle with respect to the surface of the substrate 2 is propagated upwards also at a narrow angle. However, the semiconductor layer serving as the planarization layer 3 between the pixels is removed, such that the light is refracted at a narrower angle with respect to the surface of the substrate 2 on the interface between the atmosphere and the semiconductor layer, or on the interface between the atmosphere and the substrate 2. Then, the light is multiply reflected between: the side wall included in the stray light attenuating groove 5 and facing the adjacent pixel; and the side wall included in the stray light attenuating groove 5 and facing the light-emitting element. At this time, the reflection on the interface between the atmosphere and the semiconductor layer is less than 100%, and the absorption by both the atmosphere and the semiconductor layer is greater than 0%. Furthermore, the monolithic structure has a total layer thickness greater than a thickness of a conventional element structure. Hence, with repetition of multiple reflection more times, the intensity of light that can escape in the front direction is attenuated to almost 0.

As described above, the depressing-projecting structure 6 on the surface of the substrate 2, the monolithic element structure, and the semiconductor layer serving as the planarization layer 3 between the pixels can achieve advantageous effects of effectively reducing the stray light.

Optical Simulations

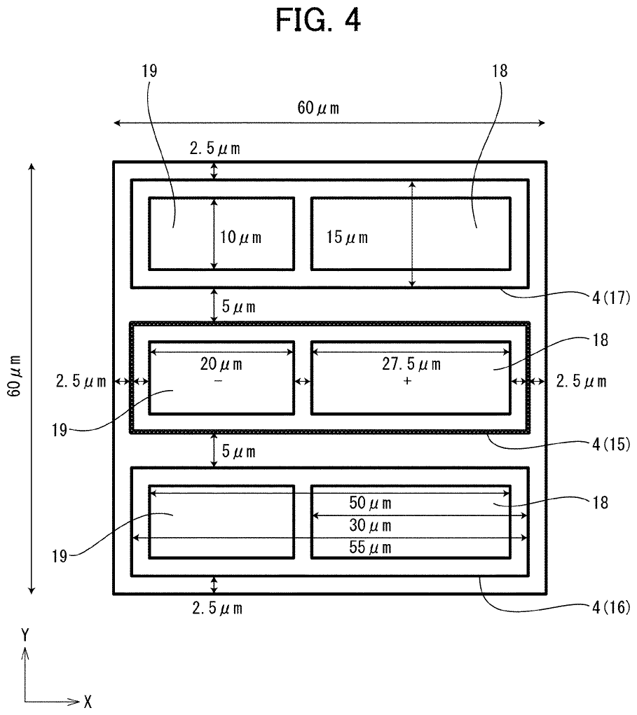

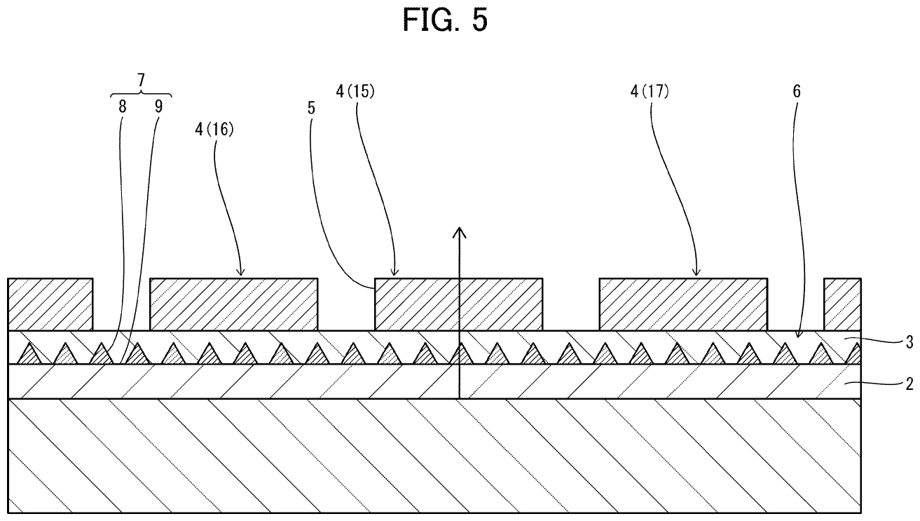

FIG. 4 is a plan view showing dimensions of micro LED elements 4 as a condition for optical simulations of the LED array 1. FIG. 5 is a cross-sectional view showing a condition for the optical simulations of the LED array 1. Constituent features similar to those previously described are designated with similar reference signs, and the detailed description of such constituent features will not be elaborated upon repeatedly.

A third light-emitting element 17 that emits a red light, a first light-emitting element 15 that emits a blue light, and a second light-emitting element 16 that emits a green light are arranged in the Y-direction to constitute one pixel. Then, around the one pixel, adjacent pixels having the same configuration are arranged in an array.

Each of the third light-emitting element 17, the first light-emitting element 15, and the second light-emitting element 16 includes the anode 18 and the cathode 19. When the anode 18 and the cathode 19 of each light-emitting element are connected to a power supply, the entire light-emitting element is illuminated. The optical simulations find out how light is oriented when the first light-emitting element 15 is illuminated blue with a wavelength of 450 nm.

As illustrated in FIG. 5, the depressing-projecting structure 6 is formed on the substrate 2. Then, on the planarization layer 3, the first light-emitting element 15, the second light-emitting element 16, and the third light-emitting element 17 are arranged. The first light emitting element and the second light emitting element 16, and the first light emitting element 15 and the third light emitting element 17, are completely separated from each other by the stray light attenuating groove 5.

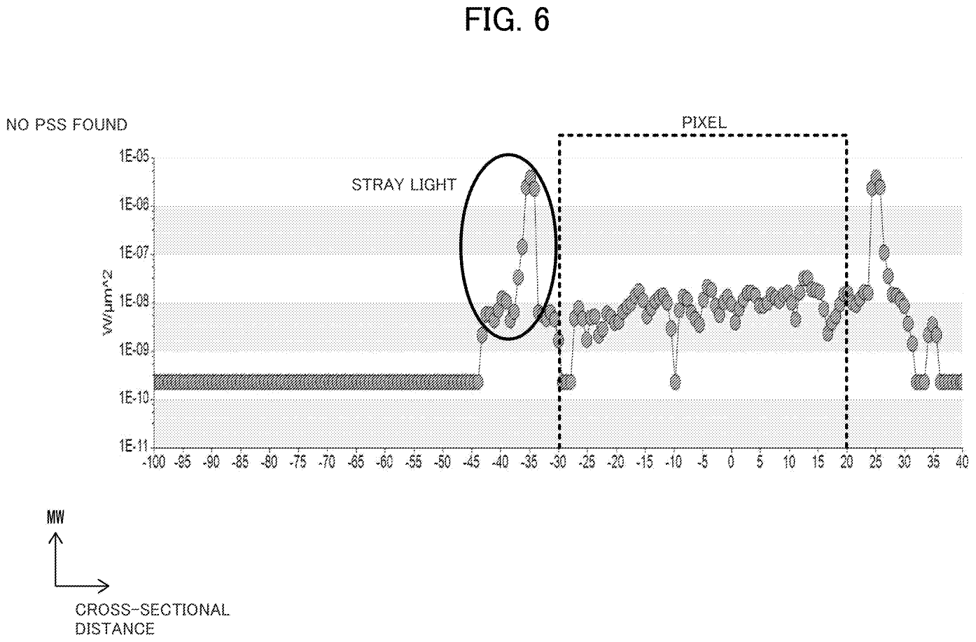

FIG. 6 is a graph showing a simulation result of stray light generated when the depressing-projecting structure 6 is not formed on the substrate 2. Constituent features similar to those previously described are designated with similar reference signs, and the detailed description of such constituent features will not be elaborated upon repeatedly.

When the depressing-projecting structure 6 is not formed on the substrate 2, as illustrated in FIG. 6, the result of optical simulation shows that stray light is generated outside a non-light-emitting pixel adjacent to the light-emitting pixel.

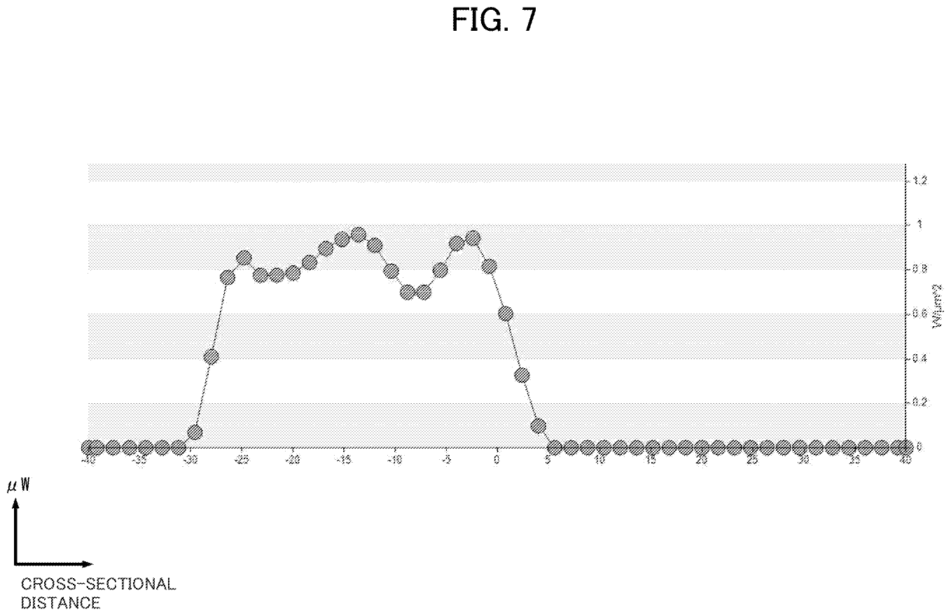

FIG. 7 is a graph showing stray light generated when the depressing-projecting structure 6 is formed on the substrate 2. Constituent features similar to those previously described are designated with similar reference signs, and the detailed description of such constituent features will not be elaborated upon repeatedly.

When the depressing-projecting structure 6 is formed on the substrate 2, as illustrated in FIG. 7, the stray light generated outside a non-light-emitting pixel adjacent to the light-emitting pixel disappears. As to this depressing-projecting structure 6, the bottom surface 9 has a dimension of 300 nm, and the inclined surface 8 has: a dimension of 300 nm in a direction perpendicular to the substrate 2; and a dimension of 250 nm in the surface direction of the substrate 2.

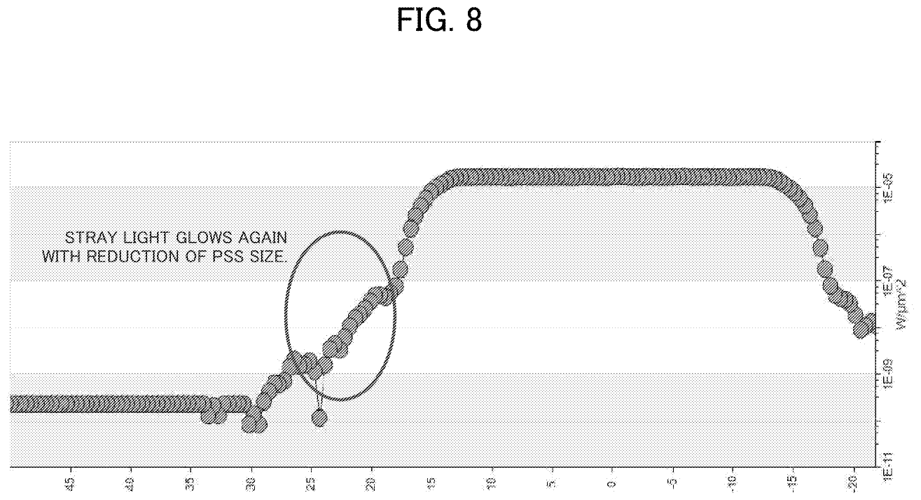

FIG. 8 is a graph showing stray light generated when dimensions of the depressing-projecting structure 6 are reduced. Constituent features similar to those previously described are designated with similar reference signs, and the detailed description of such constituent features will not be elaborated upon repeatedly.

As to this depressing-projecting structure 6, the dimension of the bottom surface 9 is set to 300 nm, the dimension of the inclined surface 8 perpendicular to the substrate 2 is reduced from 300 nm to 150 nm, and the dimension of the inclined surface 8 in the surface direction of the substrate 2 is set to 250 nm. As illustrated in FIG. 8, the stray light glows again in a non-light-emitting pixel adjacent to the light-emitting pixel.

This is probably because, for the blue light having a wavelength of 450 nm, the dimension of 150 nm for the inclined surface 8 is less of ½ of the wavelength of the blue light. In such a dimension, the blue light having the wavelength of 450 nm does not react as either depressions or projections. On the other hand, the dimension of the inclined surface 8 in FIG. 7 is 300 nm, which is ½ or more than the wavelength of the blue light. Therefore, the blue light having the wavelength of 450 nm reacts as depressions and projections. The blue light is reflected on the inclined surface 8 and guided to the stray light attenuating groove 5. That is probably why the stray light is multiply reflected on both side walls of the stray light attenuating groove 5, and disappears.

Critical Significance of Depth of Stray Light Attenuating Groove 5

Described below is critical significance of a depth of the stray light attenuating groove greater than 4 μm.

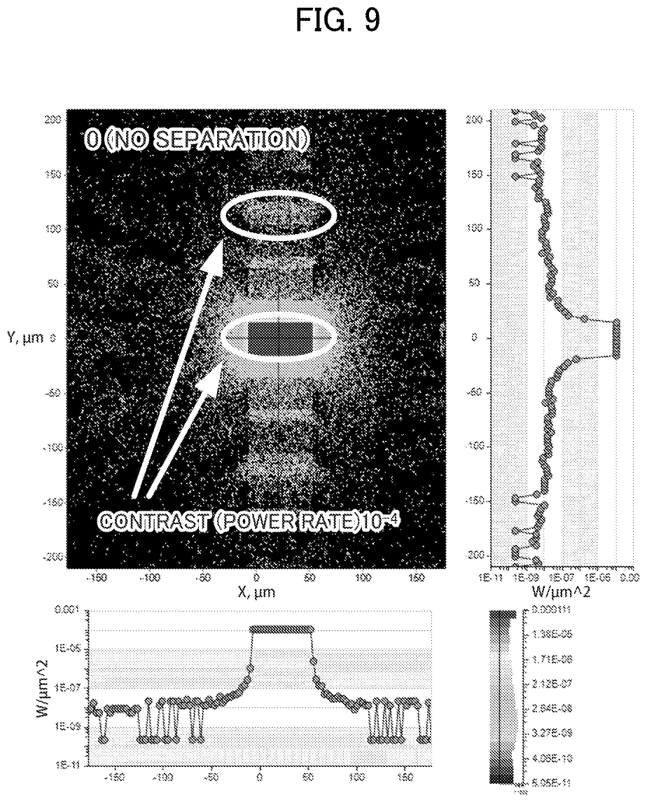

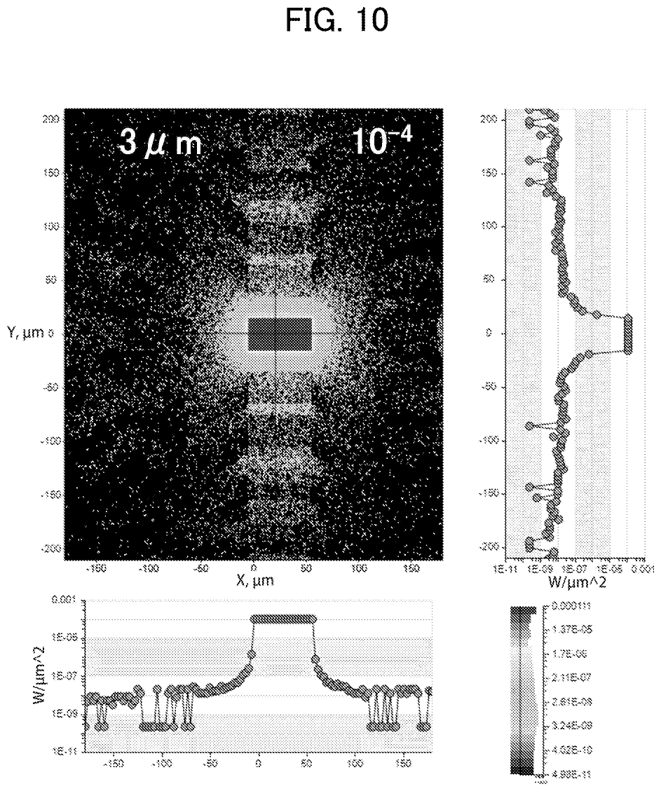

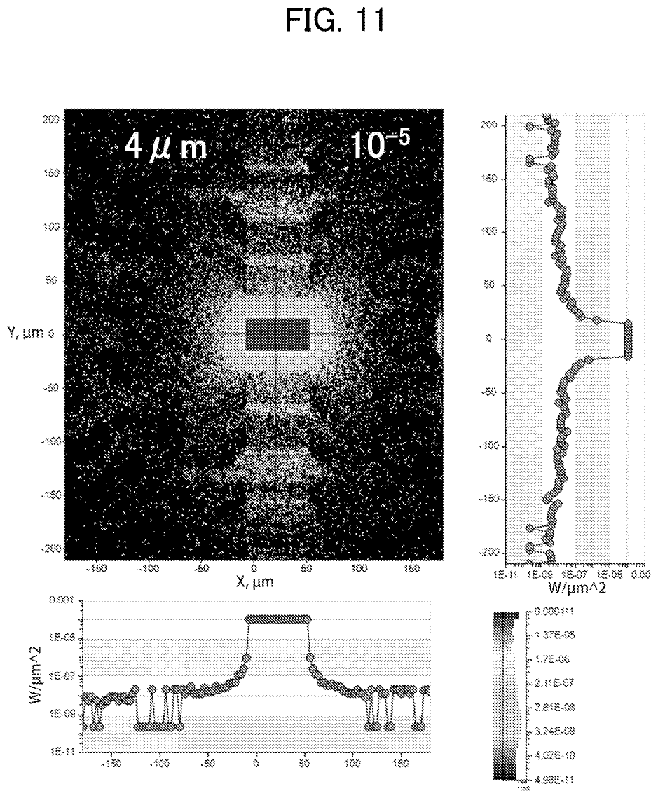

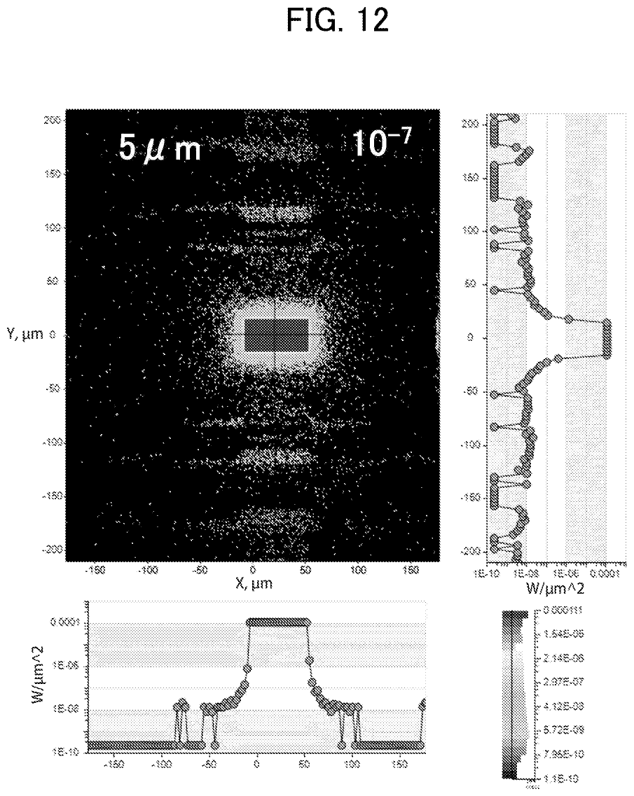

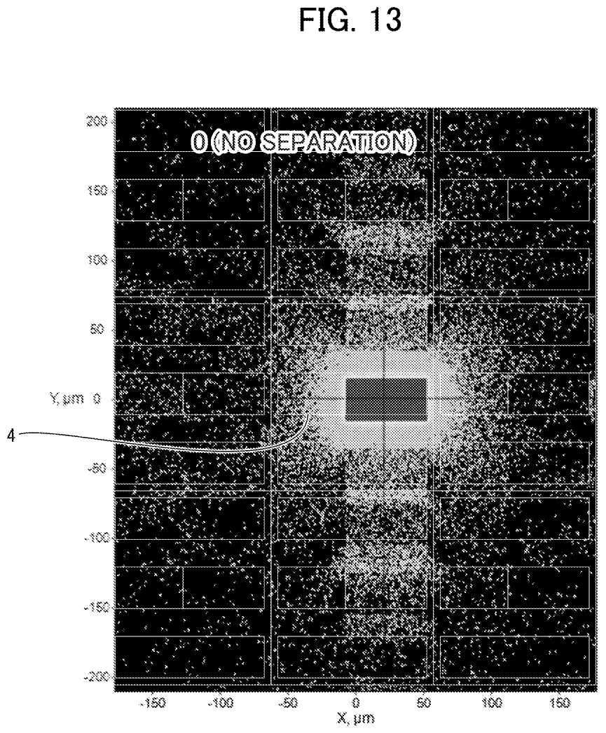

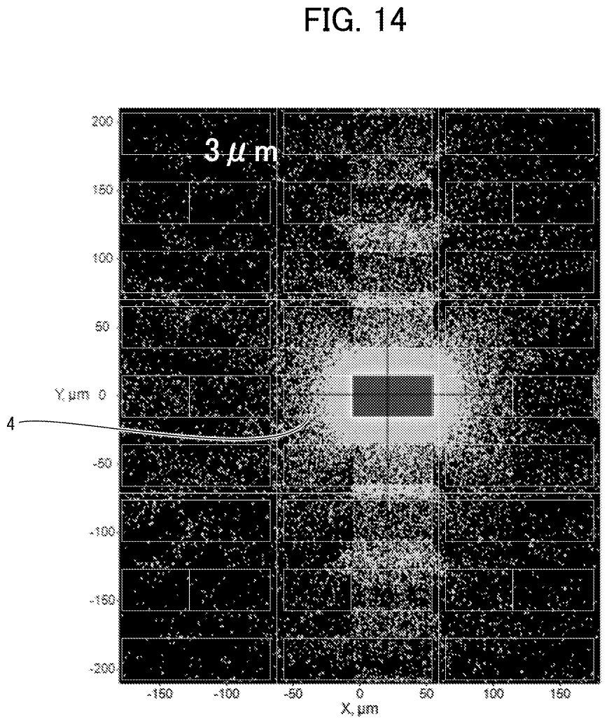

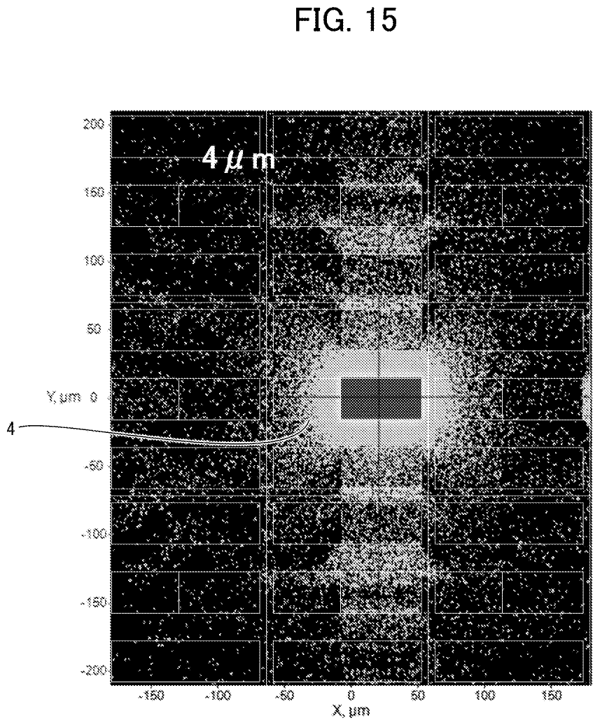

FIG. 9 is an image showing a simulation result of stray light observed when no stray light attenuating groove 5 is provided to the LED array 1. FIG. 10 is an image showing a simulation result of stray light observed when the stray light attenuating groove 5 having a depth of 3 μm is provided. FIG. 11 is an image showing a simulation result of stray light observed when the stray light attenuating groove 5 having a depth of 4 μm is provided. FIG. 12 is an image showing a simulation result of stray light observed when a stray light attenuating groove having a depth of 5 μm is provided. FIG. 13 is an image showing a simulation result of stray light observed when FIG. 9 is overlapped with shapes of pixels. FIG. 14 is an image showing a simulation result of stray light observed when FIG. 10 is overlapped with shapes of pixels. FIG. 15 is an image showing a simulation result of stray light observed when FIG. 11 is overlapped with shapes of pixels. FIG. 16 is an image showing a simulation result of stray light observed when FIG. 12 is overlapped with shapes of pixels. Constituent features similar to those previously described are designated with similar reference signs, and the detailed description of such constituent features will not be elaborated upon repeatedly.

The series of simulation results are calculated according to the same conditions as those of the optical simulations described above with reference to FIGS. 4 to 8, and under the condition that the depressing-projecting structure 6 is not formed on the substrate 2. In FIGS. 9 to 16, the stray light emitted from the micro LED element 4 is represented by white spots.

If the stray light attenuating groove 5 is not provided to the LED array 1, as illustrated in FIGS. 9 and 13, stray light is generated because of light emitted from the micro LED element 4.

If the stray light attenuating groove 5 having a depth of 3 μm is provided, as illustrated in FIGS. 10 and 14, the stray light is still generated because of light emitted from the micro LED element 4. The stray light is rarely reduced. If the stray light attenuating groove 5 having a depth of 4 μm is provided, as illustrated in FIGS. 11 and 15, stray light is still generated because of light emitted from the micro LED element 4. The stray light is rarely reduced.

However, if the stray light attenuating groove 5 having a depth of 5 μm is provided, as illustrated in FIGS. 12 and 16, the stray light generated because of the light emitted from the micro LED element 4 is dramatically reduced.

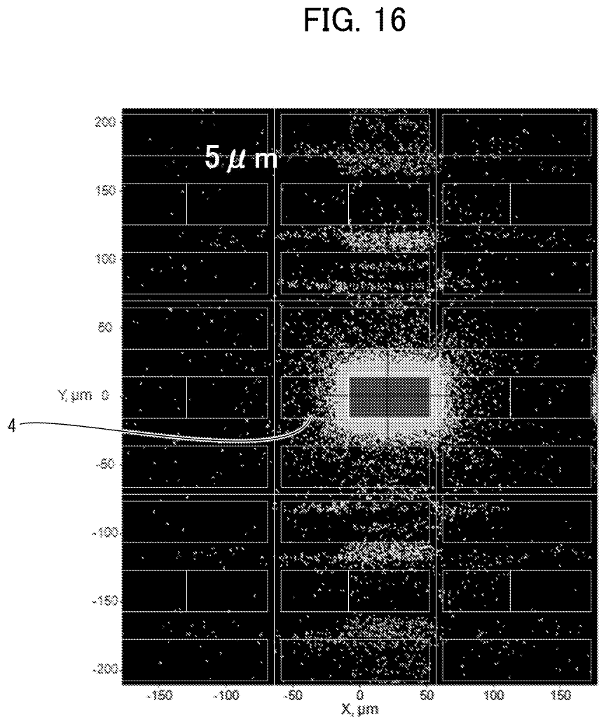

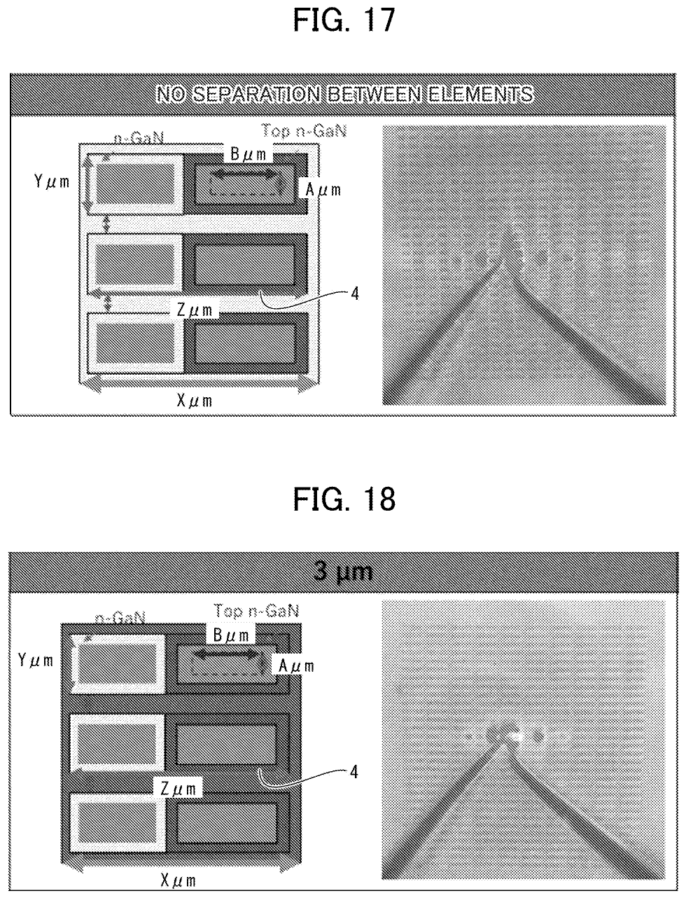

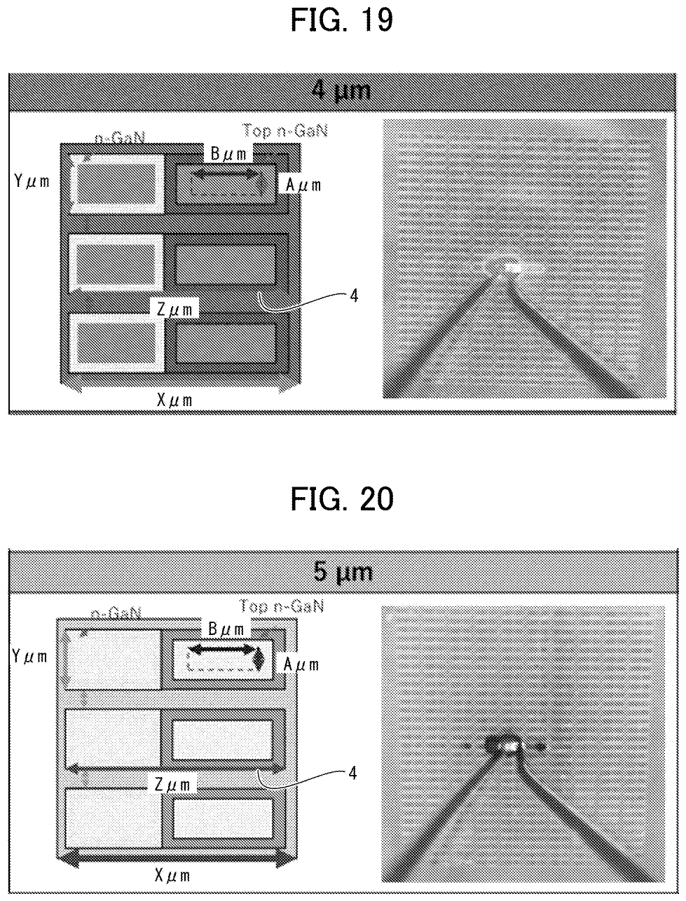

FIG. 17 is an image showing an experimental result of stray light observed when no stray light attenuating groove 5 is formed. FIG. 18 is an image showing an experimental result of stray light observed when the stray light attenuating groove 5 having a depth of 3 μm is formed. FIG. 19 is an image showing an experimental result of stray light observed when the stray light attenuating groove 5 having a depth of 4 μm is formed. FIG. 20 is an image showing an experimental result of stray light observed when the stray light attenuating groove 5 having a depth of 5 μm is formed. Constituent features similar to those previously described are designated with similar reference signs, and the detailed description of such constituent features will not be elaborated upon repeatedly.

Similar to the results of the optical simulations described with reference to FIGS. 9 to 16, if no stray light attenuating groove 5 is provided as illustrated in FIG. 17, stray light is generated because of the light emitted from the micro LED element 4. If the stray light attenuating groove 5 having a depth of 3 μn is provided, as illustrated in FIG. 18, the stray light is still generated because of the light emitted from the micro LED element 4. The stray light is rarely reduced. If the stray light attenuating groove 5 having a depth of 4 μm is provided, as illustrated in FIG. 19, the stray light is still generated because of the light emitted from the micro LED element 4. The stray light is rarely reduced.

However, if the stray light attenuating groove 5 having a depth of 5 μm is provided, as illustrated in FIG. 20, the stray light generated because of the light emitted from the micro LED element 4 is dramatically reduced.

As described above, both the experimental results and the simulation results show that an effect can be confirmed of reducing the stray light when the stray light attenuating groove 5 with a depth exceeding 4 μm is provided between the micro LED elements 4. However, the effect is not sufficient in reducing the stray light. Hence, the depressing-projecting structure 6 is additionally introduced to successfully reduce the stray light.

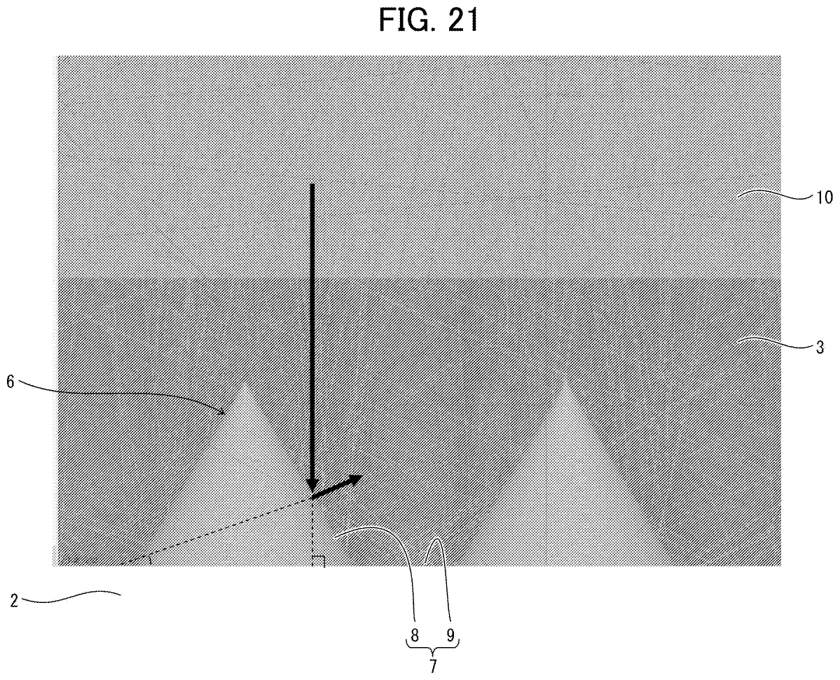

FIG. 21 is an image showing a result of tracking light rays around the depressing-projecting structure 6. Constituent features similar to those previously described are designated with similar reference signs, and the detailed description of such constituent features will not be elaborated upon repeatedly.

As illustrated in FIG. 21, light is incident from the first light-emitting layer 10 on the inclined surface 8 of the depressing-projecting structure 6 at an angle nearly perpendicular to the surface of the substrate 2. The light is reflected at a narrow angle with respect to the surface of the substrate 2. The light reflected on the inclined surface 8 is incident on the stray light attenuating groove 5, multiply reflected on one side wall and another side wall of the stray light attenuating groove 5, and scattered and attenuated. As a result, the stray light propagating from the light-emitting pixel to the non-light-emitting pixel is reduced.

### SUMMARY

The LED array 1 according to an aspect of the present disclosure includes: a substrate 2 having a depressing-projecting structure 6 formed on a surface of the substrate 2; a planarization layer 3 formed on the depressing-projecting structure 6; a plurality of micro LED elements 4 each of which is formed on the planarization layer 3; and a stray light attenuating groove 5 formed between a pair of adjacent micro LED elements 4 among the plurality of micro LED elements 4, and extending from toward the pair of adjacent micro LED elements 4 to toward the depressing-projecting structure 6 at least part way of the planarization layer 3.

According to the above configuration, light emitted from one of the pair of adjacent micro LED elements among the plurality of micro LED elements is reflected on the depressing-projecting structure of the substrate. The reflected light travels toward the stray light attenuating groove formed between the pair of adjacent micro LED elements, and extending from toward the pair of adjacent micro LED elements to toward the depressing-projecting structure at least part way of the planarization layer. Then, the light reflected on the depressing-projecting structure of the substrate is incident on the stray light attenuating groove. The light incident on the stray light attenuating groove is multiply reflected on both side walls of the stray light attenuating groove. Such features can attenuate stray light due to the light emitted from the micro LED element.

In the LED array 1 of a second aspect of the present disclosure according to the first aspect, the stray light attenuating groove preferably has a depth exceeding 4 μm.

According to the configuration described above, the stray light attenuating groove has a sufficiently large size to multiply reflect and attenuate the light incident on the stray light attenuating groove.

In the LED array 1 of a third aspect of the present disclosure according to the first or the second aspect, the depressing-projecting structure 6 preferably includes an inclined surface 8, and a dimension of the inclined surface 8 in a direction in parallel with the substrate 2 is preferably ½ or more of a wavelength of light emitted from the micro LED element 4, and 2 μm or less.

According to the above configuration, the dimension, of the inclined surface, in the direction in parallel with the substrate is ½ or more of the wavelength of the light emitted from the micro LED element, and 2 μm or less. Hence, the light emitted from the micro LED element 4 reacts as depressions and projections with respect to the inclined surface of the depressing-projecting structure.

In the LED array 1 of a fourth aspect of the present disclosure according to the first or the second aspect, the depressing-projecting structure preferably includes an inclined surface 8, and a dimension of the inclined surface 8 in a direction perpendicular to the substrate 2 is preferably ½ or more of a wavelength of light emitted from the micro LED element 4, and 2 μm or less.

According to the above configuration, the dimension, of the inclined surface, in the direction perpendicular to the substrate is ½ or more of the wavelength of the light emitted from the micro LED element, and 2 μm or less. Hence, the light emitted from the micro LED element 4 reacts as depressions and projections with respect to the inclined surface of the depressing-projecting structure.

In the LED array 1 of a fifth aspect of the present disclosure according to the first or the second aspect, the depressing-projecting structure 6 preferably includes an inclined surface 8, and the inclined surface 8 is preferably inclined at an inclination angle at which light emitted from the micro LED element 4 is reflected and guided to the stray light attenuating groove 5.

According to the above configuration, the light emitted from the micro LED element is successfully reflected on the inclined surface and guided to the stray light attenuating groove.

In the LED array 1 of a sixth aspect of the present disclosure according to the first or the second aspect, the depressing-projecting structure 6 preferably includes a plurality of depressing-projecting units 7, and one or more of the depressing-projecting units 7 are preferably provided per a region corresponding to each of the plurality of micro LED elements 4.

According to the above configuration, the depressing-projecting units increase in density. Hence, the light emitted from the micro LED element is successfully reflected more and guided to the stray light attenuating groove. Such a feature can attenuate large amount of stray light due to the light emitted from the micro LED element.

In the LED array 1 of a seventh aspect of the present disclosure according to the first or the second aspect, the depressing-projecting structure 6 preferably includes a projecting portion formed on the surface, on the projecting portion, an inclined surface 8 is preferably formed, the depressing-projecting structure 6 preferably further includes a bottom surface 9 connected to the inclined surface 8, and the bottom surface 9 preferably has a shape of a circle, an ellipse, or a polygon.

According to the above configuration, the inclined surface is provided to the projecting portion formed on the surface of the substrate. The inclined surface can reflect the light emitted from the micro LED element, and guide the light to the stray light attenuating groove.

In the LED array 1 of an eighth aspect of the present disclosure according to the first or the second aspect, the depressing-projecting structure 6 preferably includes a depressing portion formed on the surface, on the depressing portion, an inclined surface 8 is preferably formed, the depressing-projecting structure 6 preferably further includes a bottom surface 9 connected to the inclined surface 8, and the bottom surface preferably has a shape of a circle, an ellipse, or a polygon.

According to the above configuration, the inclined surface is provided to the depressing portion formed on the surface of the substrate. The inclined surface can reflect the light emitted from the micro LED element, and guide the light to the stray light attenuating groove.

In the LED array 1 of a ninth aspect of the present disclosure according to the first or the second aspect, the micro LED element 4 preferably has a multilayer stacking structure including: a first light-emitting layer 10 that emits light in a first color; a second light-emitting layer 11 that emits light in a second color; and a third light-emitting layer 12 that emits light in a third color, the first light-emitting layer 10, the second light-emitting layer 11, and the third light-emitting layer 12 being stacked on top of another.

According to the above configuration, the micro LED element has a multilayer stacking structure. The multilayer stacking structure allows the stray light attenuating groove: to be formed deeply between an adjacent pair of micro LED elements among a plurality of micro LED elements; and to extend from the micro LED elements toward the depressing-projecting structure and reach at least part way of the planarization layer. Thanks to such a feature, the light incident on the stray light attenuating groove can be reflected multiply on both side walls formed deeply in the stray light attenuating groove, and significantly attenuated.

In the LED array 1 of a tenth aspect of the present disclosure according to the ninth aspect, the micro LED element 4 preferably includes: a first semiconductor layer 13 provided between the first light-emitting layer 10 and the second light-emitting layer 11; and a second semiconductor layer 14 provided between the second light-emitting layer 11 and the third light-emitting layer 12.

According to the configuration described above, the first semiconductor layer provided between the first light-emitting layer and the second light-emitting layer, and the second semiconductor layer provided between the second light-emitting layer and the third light-emitting layer, are stacked in a multilayer staking structure. Hence, the stray light attenuating groove can be formed deeper.

In the LED array 1 of an eleventh aspect of the present disclosure according to the ninth aspect, a clearance between the first light-emitting layer and the second light-emitting layer, and a clearance between the second light-emitting layer and the third light-emitting layer, preferably have a thickness of 1 μm or more.

According to the above configuration, a clearance between the first light-emitting layer and the second light-emitting layer, and a clearance between the second light-emitting layer and the third light-emitting layer, have a thickness of 1 μm or more. Hence, the stray light attenuating groove can be formed deeper.

In the LED array 1 of a twelfth aspect of the present disclosure according to the first or the second aspect, each of the plurality of micro LED elements 4 is preferably any of: a first light-emitting element 15 including a first light-emitting layer 10 emitting light in a first color; a second light-emitting element 16 including the first light-emitting layer 10, and a second light-emitting layer 11 stacked above the first light-emitting layer 10 and emitting light in a second color; and a third light-emitting element 17 including the first light-emitting layer 10, the second light-emitting layer 11, and a third light-emitting layer 12 stacked above the second light-emitting layer 11 and emitting light in a third color.

According to the above configuration, the third light-emitting layer, the second light-emitting layer, and the first light-emitting layer, which respectively emit a red light, a green light, and a blue light, are stacked on top of another in a direction crossing the substrate 2, in order to have a monolithic structure. The monolithic structure has a total layer thickness greater than a thickness of a conventional element structure. Hence, with repetition of multiple reflection more times, the intensity of light that can escape in the front direction is attenuated to almost 0.

In the LED array 1 of a thirteenth aspect of the present disclosure according to the first or the second aspect, the stray light attenuating groove 5 preferably extends to a position in which the planarization layer 3 is left to have a thickness of 3 μm or less from the surface of the substrate 2.

According to the above configuration, the stray light attenuating groove extends to a position in which the planarization layer is left to have a thickness of 3 μm or less from the surface of the substrate. Such a feature allows the stray light attenuating groove to be formed deeply, thereby making it possible to reduce stray light propagating in a wide range.

The LED array 1 of a fourteenth aspect of the present disclosure according to the first or the second aspect preferably further includes a dielectric film formed to cover a side wall of the stray light attenuating groove 5.

The above configuration can ensure protection of the element structure and insulation between the adjacent elements.

The present invention shall not be limited to the embodiment described above, and can be modified in various manners within the scope of claims. The technical aspects disclosed in different embodiments are to be appropriately combined together to implement another embodiment. Such an embodiment shall be included within the technical scope of the present invention. Furthermore, the technical aspects disclosed in each embodiment may be combined to achieve a new technical feature. While there have been described what are at present considered to be certain embodiments of the invention, it will be understood that various modifications may be made thereto, and it is intended that the appended claims cover all such modifications as fall within the true spirit and scope of the invention.

What is claimed is:

1. An LED array, comprising:
a substrate having a depressing-projecting structure formed on a surface of the substrate;
a planarization layer formed on the depressing-projecting structure;
a plurality of micro LED elements each of which is formed on the planarization layer; and
a stray light attenuating groove formed between a pair of adjacent micro LED elements among the plurality of micro LED elements, and extending from toward the pair of micro LED elements to toward the depressing-projecting structure at least part way of the planarization layer.

2. The LED array according to claim 1,
wherein the stray light attenuating groove has a depth exceeding 4 μm.

3. The LED array according to claim 1,
wherein the depressing-projecting structure includes an inclined surface, and
a dimension of the inclined surface in a direction in parallel with the substrate is ½ or more of a wavelength of light emitted from the micro LED element, and 2 μm or less.

4. The LED array according to claim 1,
wherein the depressing-projecting structure includes an inclined surface, and
a dimension of the inclined surface in a direction perpendicular to the substrate is ½ or more of a wavelength of light emitted from the micro LED element, and 2 μm or less.

5. The LED array according to claim 1,
wherein the depressing-projecting structure includes an inclined surface, and
the inclined surface is inclined at an inclination angle at which light emitted from the micro LED element is reflected and guided to the stray light attenuating groove.

6. The LED array according to claim 1,
wherein the depressing-projecting structure includes a plurality of depressing-projecting units, and
one or more of the depressing-projecting units are provided per a region corresponding to each of the plurality of micro LED elements.

7. The LED array according to claim 1,
wherein the depressing-projecting structure includes a projecting portion formed on the surface,
on the projecting portion, an inclined surface is formed,
the depressing-projecting structure further includes a bottom surface connected to the inclined surface, and
the bottom surface has a shape of a circle, an ellipse, or a polygon.

8. The LED array according to claim 1,
wherein the depressing-projecting structure includes a depressing portion formed on the surface,
on the depressing portion, an inclined surface is formed,
the depressing-projecting structure further includes a bottom surface connected to the inclined surface, and
the bottom surface has a shape of a circle, an ellipse, or a polygon.

9. The LED array according to claim 1,
wherein the micro LED element has a multilayer stacking structure including: a first light-emitting layer configured to emit light in a first color; a second light-emitting layer configured to emit light in a second color; and a third light-emitting layer configured to emit light in a third color, the first light-emitting layer, the second light-emitting layer, and the third light-emitting layer being stacked on top of another.

10. The LED array according to claim 9,
wherein the micro LED element includes: a first semiconductor layer provided between the first light-emitting layer and the second light-emitting layer; and a second semiconductor layer provided between the second light-emitting layer and the third light-emitting layer.

11. The LED array according to claim 9,
wherein a clearance between the first light-emitting layer and the second light-emitting layer, and a clearance between the second light-emitting layer and the third light-emitting layer, have a thickness of 1 μm or more.

12. The LED array according to claim 1,
wherein each of the plurality of micro LED elements is any of:
a first light-emitting element including a first light-emitting layer configured to emit light in a first color;
a second light-emitting element including the first light-emitting layer, and a second light-emitting layer stacked above the first light-emitting layer and configured to emit light in a second color; and
a third light-emitting element including the first light-emitting layer, the second light-emitting layer, and a third light-emitting layer stacked above the second light-emitting layer and configured to emit light in a third color.

13. The LED array according to claim 1,
wherein the stray light attenuating groove extends to a position in which the planarization layer is left to have a thickness of 3 μm or less from the surface of the substrate.

14. The LED array according to claim 1, further comprising
a dielectric film formed to cover a side wall of the stray light attenuating groove.

15. The LED array according to claim 2,
wherein the depressing-projecting structure includes an inclined surface, and
a dimension of the inclined surface in a direction in parallel with the substrate is ½ or more of a wavelength of light emitted from the micro LED element, and 2 μm or less.

16. The LED array according to claim 2,
wherein the depressing-projecting structure includes an inclined surface, and
a dimension of the inclined surface in a direction perpendicular to the substrate is ½ or more of a wavelength of light emitted from the micro LED element, and 2 μm or less.

17. The LED array according to claim 2,
wherein the depressing-projecting structure includes an inclined surface, and
the inclined surface is inclined at an inclination angle at which light emitted from the micro LED element is reflected and guided to the stray light attenuating groove.

18. The LED array according to claim 2,
wherein the depressing-projecting structure includes a plurality of depressing-projecting units, and
one or more of the depressing-projecting units are provided per a region corresponding to each of the plurality of micro LED elements.

19. The LED array according to claim 2,
wherein the depressing-projecting structure includes a projecting portion formed on the surface,
on the projecting portion, an inclined surface is formed,
the depressing-projecting structure further includes a bottom surface connected to the inclined surface, and
the bottom surface has a shape of a circle, an ellipse, or a polygon.

20. The LED array according to claim 2,
wherein the depressing-projecting structure includes a depressing portion formed on the surface,
on the depressing portion, an inclined surface is formed,
the depressing-projecting structure further includes a bottom surface connected to the inclined surface, and
the bottom surface has a shape of a circle, an ellipse, or a polygon.
